(19) United States
(12) Patent Application Publication
(10) Pub. No.: US 2024/0324274 A1
(43) Pub. Date: Sep. 26, 2024

(54) TRANSPARENT STRUCTURE FOR EMITTING LIGHT

(71) Applicants: Nextgen Nano Limited, London (GB); North Carolina State University, Raleigh, NC (US)

(72) Inventors: Franky So, Raleigh, NC (US); Hamna Iqbal, Raleigh, NC (US); Hossein Ardekani, Raleigh, NC (US); Matthew Stone, Raleigh, NC (US)

(21) Appl. No.: 18/189,347

(22) Filed: Mar. 24, 2023

(51) Int. Cl. H10K 50/828; H10K 50/12; H10K 50/15; H10K 50/16; H10K 50/17; H10K 50/816; H10K 71/16; H10K 71/60; H10K 85/10; H10K 85/30

(52) U.S. Cl. CPC H10K 50/828; H10K 50/12; H10K 50/15; H10K 50/16; H10K 50/171; H10K 50/816; H10K 71/164; H10K 71/60; H10K 85/146; H10K 85/342; H10K 2102/103; H10K 2102/20

(57) ABSTRACT

A transparent structure for emitting light is described. The transparent structure comprises an emissive layer (EML) positioned between first and second electrodes. The EML is tuned such that luminance through the first electrode is greater than luminance through the second electrode.

### FIELD

The subject disclosure generally relates to light-emitting diodes (LEDs), and in particular to a transparent structure for emitting light, transparent organic light-emitting diode (TOLED), and method of manufacturing a transparent structure for emitting light.

### BACKGROUND

Transparent screens (displays) are attracting considerable interest since they can be used anywhere where glass windows are utilized. Such screens allow simultaneous display of information and visibility of surrounding environment. Transparent displays can be implemented in various fields such as augmented reality (AR), automotive industry, heads-up displays (HUD), and security technology.

Among all technologies developed to manufacture modern displays, organic light emitting diodes (OLEDs) are excellent candidates to make transparent displays due to their light weight and superior optical performance. In LEDs, electrons and holes recombine to release energy in the form of photons, light, when voltage is applied across electrodes of the LED. Various LEDs exist in the market such as thin-film LEDs which include OLEDs, quantum dot LEDs (QLEDS), and perovskite LEDs (PeLEDs). In displays, OLEDs generally provide better picture quality and greater contrast when compared with other LED types.

An OLED is composed of several layers of organic material, including the light-emitting source, sandwiched between two electrodes. The organic stack is generally transparent to the visible light. By choosing the electrodes (anode and cathode) from the family of transparent conductive oxides (TCOs) or thin metal films an entire display panel of OLEDs becomes transparent to ambient light. In operation, such transparent organic light emitting diodes (TOLEDs) emit light through both transparent electrodes.

Improvements and/or alternatives to existing transparent structure for emitting light are desired.

This background serves only to set a scene to allow a person skilled in the art to better appreciate the following description. Therefore, none of the above discussion should necessarily be taken as an acknowledgement that that discussion is part of the state of the art or is common general knowledge. One or more aspects/embodiments of the disclosure may or may not address one or more of the background issues.

### SUMMARY

In general, transparent organic light emitting diodes (TOLEDs) emit light through both transparent electrodes, hence they may be referred to as double-sided emitters. It is of particular interest to add a privacy feature to a TOLED, making the displayed information visible only on one side.

Existing privacy solutions include the addition of a tintable window having an electrochromic device coextensively disposed with a TOLED array. A further solution includes the addition of active shutters placed on a face of a TOLED. The active shutters are electrically operable to transition between transparent and opaque states.

The addition of these elements to a TOLED results in a larger form factor making the TOLED less suitable for certain applications. Additionally, the requirement for power to an electrochromic device or active shutter results in additional power consumption. Alternatives are accordingly desired.

Accordingly, in an aspect there is provided a transparent structure for emitting light, the transparent structure comprising an emissive layer (EML) positioned between first and second electrodes, the EML tuned such that luminance through the first electrode is greater than luminance through the second electrode. Such luminance may be observable in use.

The EML being tuned may consist of or comprise a material or thickness of the EML being selected such that luminance through the first electrode is greater than luminance through the second electrode in use. The EML may consist of or comprise a stack of layers. In particular, the EML may consist of or comprises a stack of organic layers, i.e., an organic stack. As such, the EML being tuned such that luminance through the first electrode is greater than luminance through the second electrode may consist of or comprise multiple layers of the EML being tuned such that luminance through the first electrode is greater than luminance through the second electrode in use. This may consist of or comprise selecting materials and/or thickness of the layers.

Luminance through the first electrode is a measure of the intensity of light emitted through the first electrode in a first direction. Luminance through the second electrode is a measure of the intensity of light emitted through the second electrode in a second direction. The second direction is opposite the first direction. In other words, the EML is tuned such that the intensity of light emitted through the first electrode is greater than the intensity of light emitted through the second electrode. As the light emitted through the first electrode is greater than the light emitted through the second electrode, a viewer adjacent the second electrode may not see any visible light, while a viewer adjacent the first electrode may view light. In this way, the transparent structure may allow for privacy of emitted light in that the light may only be visible from one side of the structure.

The transparent structure may be arranged in an array. The array may form part of a display panel such as a display panel used for displaying moving or still images. The display panel may form part of a computing device, e.g., a computing device of a mobile terminal. Such a transparent structure may thus allow for content displayed on the display panel to be visible from one side of the panel only, thereby ensuring privacy of the content.

The EML may be tuned such that luminance through the first electrode is at least and/or approximately ten times greater than luminance through the second electrode.

The first electrode may comprise indium tin oxide (ITO). The first electrode may have a thickness from 50 nm to 150 nm. The first electrode may have a thickness of 120±20 nm.

The second electrode may comprise silver. The second electrode may comprise aluminium. The second electrode may comprise silver and aluminium. The second electrode may have a thickness of 20±2 nm, 21±2 nm or 22±2 nm. The second electrode may comprise an aluminium layer and a silver layer. The aluminium layer may have a thickness of 1±1 nm. The silver layer may have a thickness of 19±2 nm, 20±2 nm or 21±2 nm.

The EML may comprise 4,4′-Bis(N-carbazolyl)-1,1′-biphenyl (CBP) doped with 7% Ir(ppy)₂acac. The EML may have a thickness of 20±5 nm.

The transparent structure may comprise an electron injection layer (EIL), an electron transport layer (ETL), a hole blocking layer (HBL), a hole transport layer (HTL), and a hole injection layer (HIL), and combinations thereof.

The EIL may comprise caesium carbonate (CS₂CO₃). The EIL may have a thickness of 2±2 nm.

The ETL may comprise bathophenanthroline (BPhen). The BPhen may have a thickness of 35±10 nm or 40±10 nm. The ETL may have a thickness of 40±10 nm. The ETL may have a thickness of 35±10 nm. The ETL may comprise 2,2′,2″-(1,3,5-Benzinetriyl)-tris(1-phenyl-1-H-benzimidazole) (TPBi) or 2,9-Dinaphthalen-2-yl-4,7-diphenyl-1,10-phenanthroline (NBphen). The TPBi or NBphen may have a thickness of 30±10 nm. The ETL may have a thickness of 30±10 nm.

The HBL may comprise 4,6-Bis(3,5-di(pyridin-3-yl)phenyl)-2-methylpyrimidine, 4,6-Bis(3,5-di-3-pyridinylphenyl)-2-methylpyrimidine (B3PymPm). The HBL may have a thickness of 10±2 nm.

The HTL may comprise 1,1-Bis[(di-4-tolylamino)phenyl]cyclohexane (TAPC). The HTL may have a thickness of 120±30 nm or 130±30 nm. The HTL may comprise tris(4-carbazoyl-9-ylphenyl)amine (TCTA). The HTL may have a thickness of 100±20 nm.

The HIL may comprise 1,4,5,8,9,11-Hexaazatriphenylenehexacarbonitrile (HAT-CN). The HIL may have a thickness of 5±2 nm. The HIL may comprise molybdenum oxide (MoOₓ). The HIL may have a thickness of 2 nm±2 nm.

The HTL may have a thickness of 70-170 nm and the ETL has a thickness of 30-50 nm.

In another aspect there is provided an emissive layer (EML) for emitting light, the EML positionable between first and second electrodes to from a transparent structure, and the EML tuned such that luminance in a first direction from the EML is greater than luminance in a second direction, the second direction opposite the first direction.

The EML may comprise any of the aforementioned features and/or benefits.

According to another aspect there is provided a transparent organic light-emitting diode (TOLED) comprising an emissive layer (EML) positioned between first and second electrodes, the EML tuned such that luminance through the first electrode is greater than luminance through the second electrode.

The TOLED may comprise any of the aforementioned features and/or benefits.

According to another aspect there is provided a display panel comprising an array of light emitting pixels, each light emitting pixel comprising a transparent structure for emitting light, the transparent structure comprising an emissive layer (EML) positioned between first and second electrodes, the EML tuned such that luminance through the first electrode is greater than luminance through the second electrode.

According to another aspect there is provided a display panel comprising an array of light emitting pixels, each light emitting pixel comprising a transparent organic light-emitting diode (TOLED) comprising an emissive layer (EML) positioned between first and second electrodes, the EML tuned such that luminance through the first electrode is greater than luminance through the second electrode.

The display panel may comprise any of the aforementioned features and/or benefits.

The display panel may further comprise drivers for driving the array of light emitting pixels.

The drivers may include SCAN/(emission control) EM drivers and data drivers.

According to another aspect there is provided a method of manufacturing a transparent organic light-emitting diode (TOLED), the method comprising tuning an emissive layer (EML) positioned between first and second electrodes such that luminance through the first electrode is greater than luminance through the second electrode.

The method may further comprise:
depositing an emissive layer (EML) on a first electrode.

The method may further comprise:
depositing a second electrode on the EML.

Depositing the EML may comprise thermally evaporating the EML on the first electrode.

Depositing the second electrode may comprise thermally evaporating the second electrode on the EML.

According to another aspect there is provided a method of manufacturing a transparent organic light-emitting diode (TOLED), the method comprising:
depositing an emissive layer (EML) on a first electrode; and
depositing a second electrode on the EML, the EML tuned such that luminance through the first electrode is greater than luminance through the second electrode.

Depositing the EML may comprise thermally evaporating the EML on the first electrode.

Depositing the second electrode may comprise thermally evaporating the second electrode on the EML.

The described aspects may provide for a privacy feature which makes displayed information observable from one side only. As such the described aspects may be referred to a single-side emitter. Accordingly, the described EML may be referred to as a single-side emitter.

Features, benefits, or advantages associated with particular examples or embodiments relating to any one described aspect may equally relate to any other one or more described aspects.

Further elements of the aspects described may include one or more examples, embodiments or features in isolation or in various combinations whether or not specifically stated (including claimed) in that combination or in isolation.

### BRIEF DESCRIPTION OF THE DRAWINGS

These and other aspects of the present disclosure will now be described, by way of example only, with reference to the accompanying Figures, in which:

FIG. 1 is a diagram of an light-emitting diode (LED);

FIG. 2 is another diagram of an LED;

FIG. 3 is a diagram of a transparent organic LED (TOLED) in accordance with an aspect of the disclosure;

FIG. 4 is a diagram of an organic stack of the TOLED of FIG. 3;

FIG. 5 is a graph of electroluminescence (EL) spectrum of an emissive layer (EML) in accordance with an aspect of the disclosure;

FIG. 6 is a graph of bottom and top emission of the TOLED of FIG. 3;

FIG. 7a is a graph of current-voltage luminance curve of the TOLED of FIG. 3;

FIG. 7b is a graph of external quantum efficiency (EQE) of the TOLED of FIG. 3;

FIG. 8 is a graph of luminance ratio of the TOLED of FIG. 3;

FIG. 9 is a graph of the distribution of optical modes of the TOLED of FIG. 3;

FIG. 10 is a contour plot of a ratio of bottom/top emission as function of hole transport layer (HTL) and electron transport layer (ETL) thicknesses;

FIG. 11 is a flowchart of a method of manufacturing a transparent structure for emitting light in accordance with an aspect of the disclosure; and

FIG. 12 is a diagram of a display system including an array of light emitting pixels including a TOLED in accordance with an aspect of the disclosure.

### DETAILED DESCRIPTION

The foregoing summary, as well as the following detailed description of certain embodiments will be better understood when read in conjunction with the accompanying drawings. As will be appreciated, like reference characters are used to refer to like elements throughout the description and drawings. As used herein, an element or feature recited in the singular and preceded by the word “a” or “an” should be understood as not necessarily excluding a plural of the elements or features. Further, references to “one example” or “one embodiment” are not intended to be interpreted as excluding the existence of additional examples or embodiments that also incorporate the recited elements or features of that one example or one embodiment. Moreover, unless explicitly stated to the contrary, examples or embodiments “comprising”, “having” or “including” an element or feature or a plurality of elements or features having a particular property might further include additional elements or features not having that particular property. Also, it will be appreciated that the terms “comprises”, “has” and “includes” mean “including but not limited to” and the terms “comprising”, “having” and “including” have equivalent meanings.

As used herein, the term “and/or” can include any and all combinations of one or more of the associated listed elements or features.

It will be understood that when an element or feature is referred to as being “on”, “attached” to, “connected” to, “coupled” with, “contacting”, etc. another element or feature, that element or feature can be directly on, attached to, connected to, coupled with or contacting the other element or feature or intervening elements may also be present. In contrast, when an element or feature is referred to as being, for example, “directly on”, “directly attached” to, “directly connected” to, “directly coupled” with or “directly contacting” another element of feature, there are no intervening elements or features present.

It will be understood that spatially relative terms, such as “under”, “below”, “lower”, “over”, “above”, “upper”, “front”, “back” and the like, may be used herein for ease of describing the relationship of an element or feature to another element or feature as depicted in the figures. The spatially relative terms can however, encompass different orientations in use or operation in addition to the orientation depicted in the figures.

Reference herein to “example” means that one or more feature, structure, element, component, characteristic and/or operational step described in connection with the example is included in at least one embodiment and or implementation of the subject matter according to the present disclosure. Thus, the phrases “an example,” “another example,” and similar language throughout the present disclosure may, but do not necessarily, refer to the same example. Further, the subject matter characterizing any one example may, but does not necessarily, include the subject matter characterizing any other example.

Reference herein to “configured” denotes an actual state of configuration that fundamentally ties the element or feature to the physical characteristics of the element or feature preceding the phrase “configured to”.

Unless otherwise indicated, the terms “first,” “second,” etc. are used herein merely as labels, and are not intended to impose ordinal, positional, or hierarchical requirements on the items to which these terms refer. Moreover, reference to a “second” item does not require or preclude the existence of lower-numbered item (e.g., a “first” item) and/or a higher-numbered item (e.g., a “third” item).

As used herein, the terms “approximately” and “about” represent an amount close to the stated amount that still performs the desired function or achieves the desired result. For example, the terms “approximately” and “about” may refer to an amount that is within less than 10% of, within less than 5% of, within less than 1% of, within less than 0.1% of, or within less than 0.01% of the stated amount.

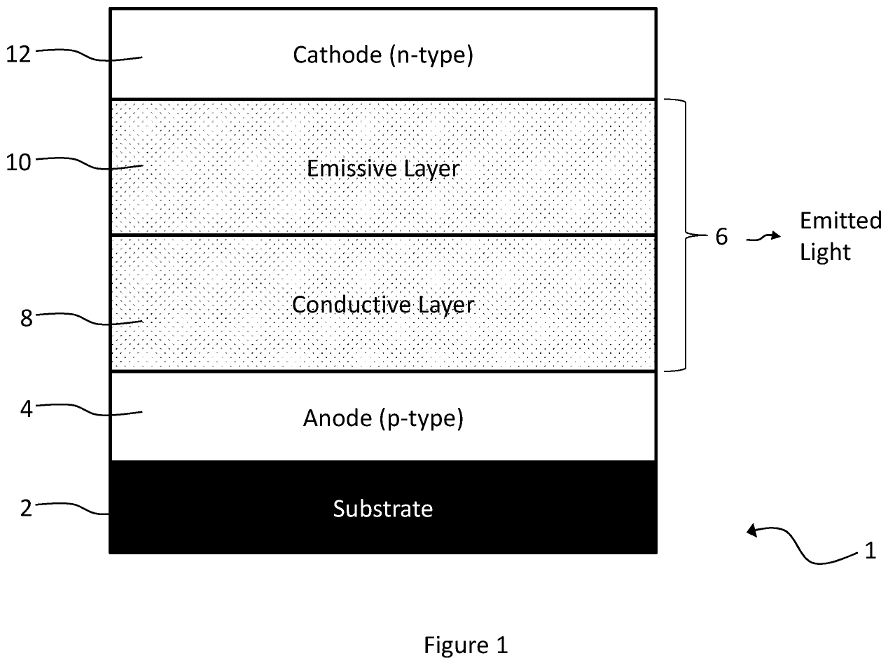

Turning now to FIG. 1 a diagram of a typical LED 1 is shown. As shown in FIG. 1, the LED 1 comprises a stack of elements. The LED 1 comprises a substrate 2 which forms a lowermost base of the LED 1. The substrate 2 may be comprised of plastic, glass, or foil. The substrate 2 may be clear. The substrate 2 supports the further layers of the LED 1. Positioned above or adjacent the substrate 2 is a lower or bottom electrode which forms an anode 4. The anode 4 forms a positive terminal in use. Positioned above the anode 4 is a layer 6. Positioned adjacent or above the layer 6 is a cathode 12 which forms a negative terminal. Electron holes (+) from the anode 4 combine with electrons (−) from the cathode 12 in the layer 6 and release photonic energy, light.

In the case of an organic LED (OLED), the layer 6 comprises organic material. The organic material is comprised of organic molecules or polymers. For example, the organic layer may comprise polyphenylene vinylene (PPV), Tris(8-hydroxyquinolinato)aluminium, polymethyl methacrylate (PMMA), organometallic chelates, e.g. Alq₃, and combinations thereof.

The layer 6 may be formed from multiple layers of elements. For example, the layer 6 may comprise a conductive layer 8 and an emissive layer 10. Electron holes (+) are transported from the anode 4 into the conductive layer 8. Electrons (−) are transported from the cathode 12 into the emissive layer 10. At the boundary between the conductive layer 8 and emissive layer 10, electrons (−) and holes (+) combine to release or emit light.

In the case of an OLED, the conductive layer 8 comprises organic molecules, e.g. organic plastic molecules. The conductive layer 8 may comprise, for example, polyaniline. The emissive layer 10 comprises organic molecules, e.g. organic plastic molecules which are different than the molecules of the conductive layer 8. The emissive layer 10 may comprise, for example, polyfluorene.

An additional layer (not shown) may be present on top of the cathode. This layer may seal and/or protect the underlying layers. This layer may be formed of glass, plastic, or other materials.

While the LED 1 has been described as having a particular physical orientation with layers above lower layers, one of skill in the art will appreciate this orientation may be varied so as all respective layer positioning is maintained. For example, the cathode 12 may be the lowermost layer, and the substrate 2 the uppermost layer. Further the cathode 12 may be rightmost layer, and the substrate 2 the leftmost layer.

Further while a bilayer structure of layer 6 has been described one of skill in the art will appreciate other configurations are possible. For example, the layer 6 may comprise, starting at the lowermost layer and moving to the uppermost layer, a hole injection layer (HIL), hole transport layer (HTL), electron blocking layer (EBL), emissive layer (EML), electron transport layer (ETL), and electron injection layer (EIL). The HIL may be adjacent the anode 4. The EIL may be adjacent the cathode 12.

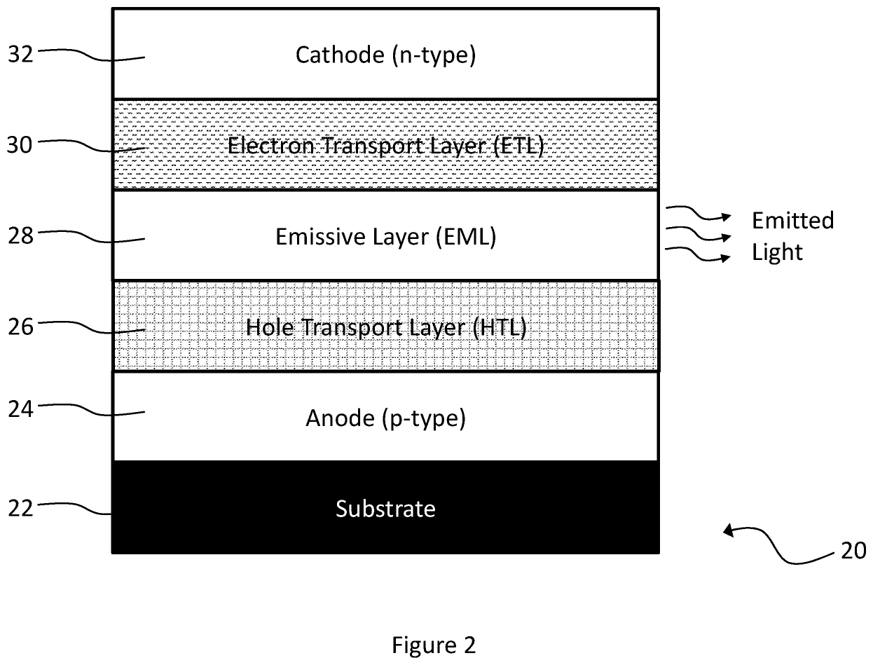

Turning now to FIG. 2 a diagram of a specific stack of layers of an LED 20 is shown. As with LED 1, the LED 20 comprises a substrate 22 which forms a lowermost base of the LED 20. The substrate 22 supports the further layers of the LED 20. Positioned on or adjacent the substrate 22 is a lower or bottom electrode which forms an anode 24. In use the anode 24 forms a positive terminal. Positioned on or adjacent the anode 24 is a HTL 26. Positioned on or adjacent the HTL 26 is a EML 28. Positioned on or adjacent the EML 28 is a ETL 30. The ETL 30 facilitates electron injection and transport from the cathode 32 to the EML 28. Positioned on or adjacent the ETL 30 is top or upper electrode which forms a cathode 32. In use the cathode 32 forms a negative terminal.

The various layers may be deposited on one another. The anode 24 is deposited on the substrate 22, the HTL 28 is deposited on the anode 24, the EML 28 is deposited on the HTL 26, the ETL 30 is deposited on the EML 28, and the cathode 32 is deposited on the ETL 30. The layers may be thermally evaporated on each other. In particular, the bottom-most layer, e.g., the anode 24 may be thermally evaporated on the substrate 22. The substrate may be pre-patterned glass. The layers may be thermally evaporated at ultra-high vacuum (10⁻⁸ Torr).

When a voltage is applied between the anode 24 and cathode 32 in a particular direction, a current between the anode 24 and cathode 32 drives movement of electron holes (+) and electrons (−). The EML 28 accepts electron holes (+) from the anode 24 via the HTL 26, and electrons (−) from the cathode 32 via the ETL 30. The electron holes (+) and electrons (−) combine in the EML 28 to generate electroluminescence (EL), i.e. emit light.

While a certain structure of the LED 20 has been described, other layers may be present. For example, an HIL and EBL may also be present adjacent the HTL 26. Further, an EIL and HBL may be present on the ETL 30. These additional layers may assist in achieving an optimized charge balance.

While the LED 20 has been described as having a particular physical orientation with layers above lower layers, one of skill in the art will appreciate this orientation may be varied so as all respective layer positioning is maintained. For example, the cathode 32 may be the lowermost layer, and the substrate 22 the uppermost layer. Further the cathode 32 may be rightmost layer, and the substrate 22 the leftmost layer.

Further, as one of skill in the art will appreciate, the position of the HTL 26 and ETL 30 may be switched to improve LED efficiency and extend the lifetime of the LED 20.

In general, the EML 28 generate EL to emit light in all directions, e.g., light is emitted at the cathode 32 and the anode 24. In conventional, LEDs 20 the cathode 32 is reflective such that emitted light is reflected by the cathode and emitted primarily out of the anode 24 and substrate 22. In this way, the majority of light is emitted at the substrate 22 and visible to a user.

In transparent organic LEDs (TOLEDs), the various layers of the LED 20 are composed of organic material and the layers are transparent. Thus, the organic stack (i.e., layers 26, 28, 30) is transparent to visible light. By selecting the anode 24 and cathode 32 from the family of transparent conductive oxides (TCOs) or thin metal films, the entire LED 20 become transparent to ambient light thereby becoming a TOLED.

In the TOLED, light emitted EML 28 is emitted via (through) both electrodes, i.e., through both cathode 32 and the anode 24. Visible light (information) is therefore visible on both sides of the LED 20. For privacy reasons, it is desirable to have light only visible from one side of the LED 20 while maintaining the transparency of both cathode 32 and anode 24. In this way information being displayed, for example by a display panel including TOLEDs, is only visible to a user on one side of the display panel rather than an unknown user on the opposite side of the display panel.

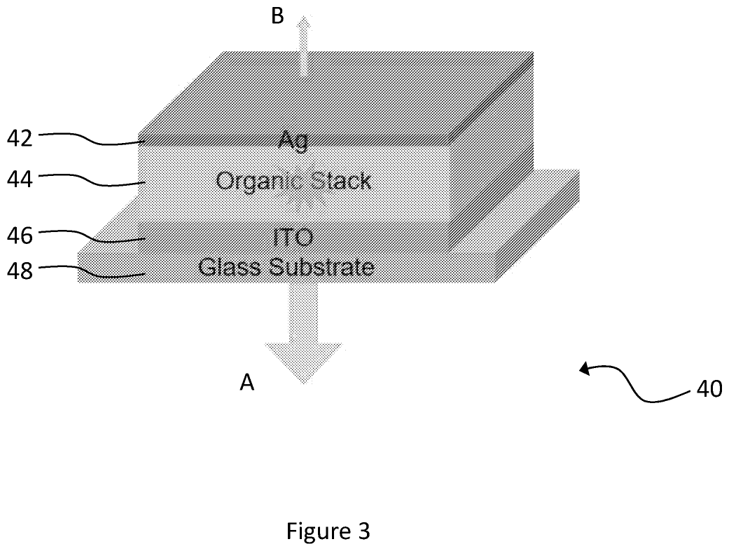

Turning now to FIG. 3, a diagram of a specific stack of layers of a TOLED 40 is shown. As with LEDs 1, 20, the OLED 40 comprises a substrate 48 which forms a lowermost base of the TOLED 40. The substrate 48 supports the further layers of the TOLED 40. In this example, the substrate 48 is glass; however, as one of skill in the art will appreciate any transparent may be used.

Positioned on or adjacent the substrate 48 is a lower or bottom electrode which forms an anode 46. In use the anode 46 forms a positive terminal. In this example, the anode 46 is chosen to be indium tin oxide (ITO) to allow the highest transparency of the TOLED 40 while providing suitable electrical conductivity. Positioned on or adjacent the anode 46 is an organic stack 44 which is tuned to emit greater luminance through the anode 46 than through the anode 42. The organic stack 44 may comprise one or more layers, and at least includes an emissive layer (EML) which is tuned as described. Luminance (emitted light) through the anode 46 is depicted by arrow A in a first direction while luminance (emitted light) through the cathode 42 is depicted by arrow B in a second direction. The second direction opposite the first direction. The emission of light occurs through the major surfaces of the TOLED 40. Positioned on or adjacent the organic stack 44 is a top or upper electrode which forms a cathode 42. In this example, the cathode 42 is silver (Ag). In use, the cathode 42 forms a negative terminal.

As mentioned, as opposed to conventional TOLEDs where thicknesses of layers of the organic stack are optimized to maximise emission, the organic stack 44 is tuned to achieve the highest bottom/top emission ratio. The bottom/top emission ratio is defined as the ratio of emission through the anode 46 compared with the emission through the cathode 42. Increasing the ratio provides a privacy feature as information is only visible on the side proximate the anode 48 and not the cathode 42 if the luminance through the cathode 42 is below the visible perceivable threshold.

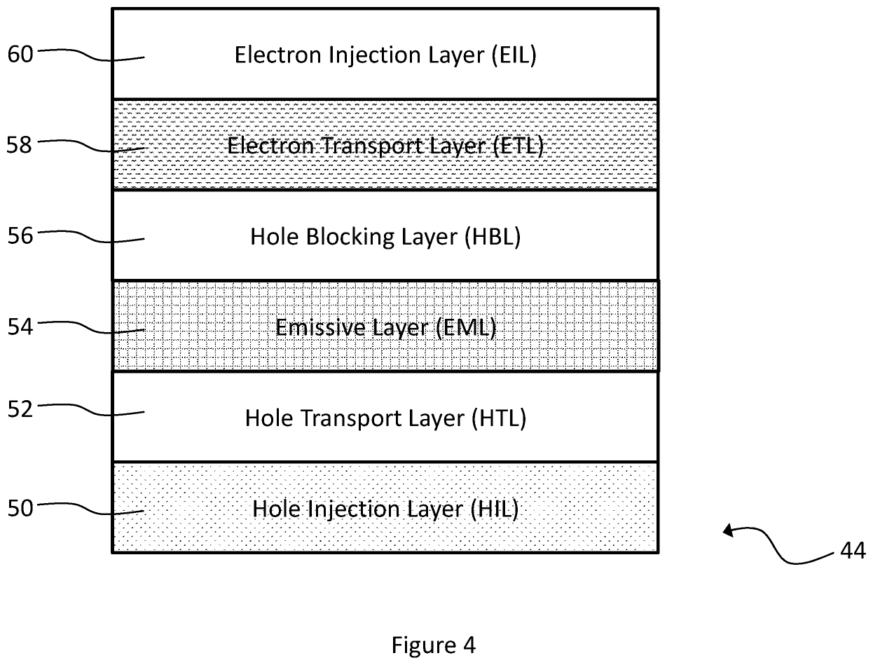

Turning now to FIG. 4, an exemplary organic stack 44 is depicted. As with the LED 20 of FIG. 2, the organic stack 44 comprises a number of layers. The layers of the organic stack 44 are similar to those described in respect of LED 20. In this instance, the stack 44 comprises a hole injection layer (HIL) 50 proximate the anode 48, a hole transport layer (HTL) 52 proximate the HIL 50, an emissive layer (EML) 54 proximate the HTL 52, a hole block layer (HBL) 56 proximate the EML 54, an electron transport layer (ETL) 58 proximate the HBL 56, and an electron injection layer (EIL) 60 proximate the ETL 58. The cathode 42 is positioned on or adjacent the EIL 60.

The layers of the organic stack 44 are tuned such that the bottom/top emission ratio of the TOLED 40 is maximised. In particular, the layers of the stack 44 are tuned such that the ratio is greater than 10.

In one example (example 1), the materials and thickness of the layers of stack 44 are selected as set out in Table 1 below.

TABLE 1
materials and thicknesses of TOLED (example 1)

| Layers | Material | Thickness | |
|---|---|---|---|
| Cathode 42 | Ag + Al | 21 ± 2 | nm |
| electron injection layer (EIL) 60 | CsCO₃ | 2 | nm |
| electron transport layer (ETL) 58 | Bphen | 40 ± 10 | nm |
| hole blocking layer (HBL) 56 | B3PYMPM | 10 ± 2 | nm |
| emissive layer (EML) 54 | (host emissive layer) | 20 ± 5 | nm |
| | CBP doped with 7% | | |
| | Ir(ppy)₂acac | | |
| hole transport layer (HTL) 52 | TAPC | 130 ± 30 | nm |
| hole injection layer (HIL) 50 | HAT-CN | 5 ± 2 | nm |
| Anode 46 | indium tin oxide (ITO) | 120 ± 20 | nm |
| Substrate 48 | Transparent glass | | |

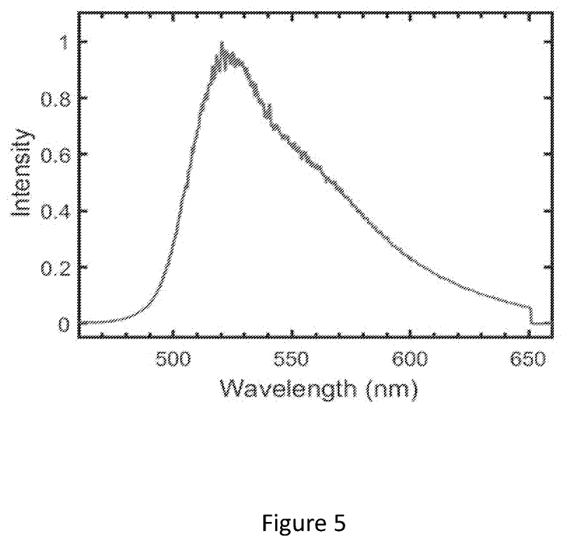

The selected EML 54 material is a common Ir(ppy)₂acac with a broad electroluminescence (EL) centred at 520 nm. The EL spectrum of the EML 54 is illustrated in FIG. 5.

The organic stack 44 is tuned to obtain the highest bottom/top emission ratio. As such, the anode 46 of ITO is paired with a cathode 42 of silver (Ag) with a thickness of 20±2 nm to decrease the transmission at the Ag/Air interface while maintaining a reasonable transparency through the TOLED 40.

The upper and lower bounds of the thicknesses of Table 1 are shown by ± symbol and indicate the range at which the deviation in the final emission ratio results (to be illustrated) remain insignificant.

One of skill in the art will appreciate other materials/thickness combinations may be used than those described. For example, the EML 54 may be selected from a wide range of organic materials usually implemented in the OLED industry. Further, any of the injection and transport layers may be substituted with other organic materials of the same class. The substitute materials should be selected to have similar refractive indices to the materials in Table 1. The refractive indices are generally in 1.7 or 1.8. Further, the energy levels of the chosen substitute materials should provide smooth charge transport from the electrodes 42, 48 to the EML 54.

Further examples (examples 2-5) of the materials and thickness of the layers of stack 44 are set out in Tables 2-5 below.

TABLE 2
materials and thicknesses of TOLED (example 2)

| Layers | Material | Thickness | |
|---|---|---|---|
| Cathode 42 | Ag + Al | 20 ± 2 | nm |
| electron injection layer (EIL) 60 | CsCO₃ | 2 | nm |
| electron transport layer (ETL) 58 | Bphen | 35 ± 10 | nm |
| hole blocking layer (HBL) 56 | B3PYMPM | 10 ± 2 | nm |
| emissive layer (EML) 54 | (host emissive layer) | 20 ± 5 | nm |
| | CBP doped with 7% | | |
| | Ir(ppy)₂acac | | |
| hole transport layer (HTL) 52 | TAPC | 130 ± 30 | nm |
| hole injection layer (HIL) 50 | MoOₓ | 2 ± 2 | nm |
| Anode 46 | indium tin oxide (ITO) | 120 ± 20 | nm |
| Substrate 48 | Transparent glass | | |

TABLE 3
materials and thicknesses of TOLED (example 3)

| Layers | Material | Thickness | |
|---|---|---|---|
| Cathode 42 | Ag + Al | 20 ± 2 | nm |
| electron injection layer (EIL) 60 | CsCO₃ | 2 | nm |
| electron transport layer (ETL) 58 | Bphen | 35 ± 10 | nm |
| hole blocking layer (HBL) 56 | B3PYMPM | 10 ± 2 | nm |
| emissive layer (EML) 54 | (host emissive layer) | 20 ± 5 | nm |
| | CBP doped with 7% | | |
| | Ir(ppy)₂acac | | |
| hole transport layer (HTL) 52 | TCTA | 100 ± 20 | nm |
| hole injection layer (HIL) 50 | HAT-CN | 5 ± 2 | nm |
| Anode 46 | indium tin oxide (ITO) | 120 ± 20 | nm |
| Substrate 48 | Transparent glass | | |

TABLE 4
materials and thicknesses of TOLED (example 4)

| Layers | Material | Thickness | |
|---|---|---|---|
| Cathode 42 | Ag + Al | 21 ± 2 | nm |
| electron injection layer (EIL) 60 | CsCO₃ | 2 | nm |
| electron transport layer (ETL) 58 | TPBi | 30 ± 10 | nm |
| hole blocking layer (HBL) 56 | B3PYMPM | 10 ± 2 | nm |
| emissive layer (EML) 54 | (host emissive layer) | 20 ± 5 | nm |
| | CBP doped with 7% | | |
| | Ir(ppy)₂acac | | |
| hole transport layer (HTL) 52 | TAPC | 120 ± 30 | nm |
| hole injection layer (HIL) 50 | HAT-CN | 5 ± 2 | nm |
| Anode 46 | indium tin oxide (ITO) | 120 ± 20 | nm |
| Substrate 48 | Transparent glass | | |

TABLE 5
materials and thicknesses of TOLED (example 5)

| Layers | Material | Thickness | |
|---|---|---|---|
| Cathode 42 | Ag + Al | 22 ± 2 | nm |
| electron injection layer (EIL) 60 | CsCO₃ | 2 | nm |
| electron transport layer (ETL) 58 | NBphen | 30 ± 10 | nm |
| hole blocking layer (HBL) 56 | B3PYMPM | 10 ± 2 | nm |
| emissive layer (EML) 54 | (host emissive layer) | 20 ± 5 | nm |
| | CBP doped with 7% | | |
| | Ir(ppy)₂acac | | |
| hole transport layer (HTL) 52 | TAPC | 120 ± 30 | nm |
| hole injection layer (HIL) 50 | HAT-CN | 5 ± 2 | nm |
| Anode 46 | indium tin oxide (ITO) | 120 ± 20 | nm |
| Substrate 48 | Transparent glass | | |

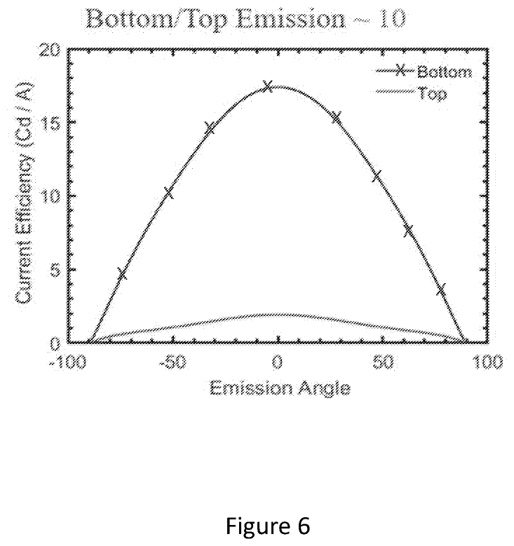

Turning now to FIGS. 6-9, simulation results of a TOLED 40 with the materials and thickness of Table 1 are illustrated.

In particular, FIG. 6 is a graph of bottom and top emission of the TOLED 40. The bottom emission (through the anode 46) ranges from 0 to approximately 18 Cd/A through an emission angle of −100 to 100 degrees. The top emission (through the cathode 42) ranges from 0 to approximately 1.8 Cd/A through an emission angle of −100 to 100 degrees. At an emission angle, the ratio of bottom to top emission is approximately 10.

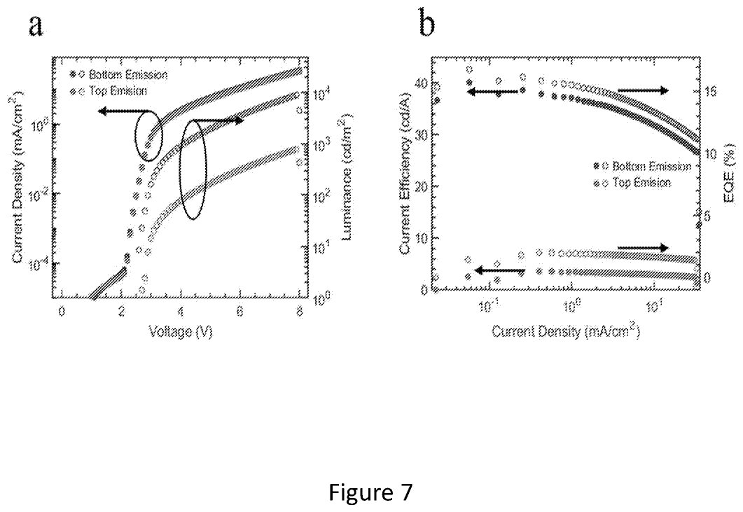

FIG. 7a illustrates current-voltage luminance curves of the TOLED 40. The top-most curve made of empty circles corresponds to the luminance at the bottom (i.e., from the anode 46) of the TOLED 40. The bottom-most curve made of empty circles corresponds to the luminance at the top (i.e., from the cathode 42) of the TOLED 40. As shown in FIG. 7a, the difference between the top and bottom luminance is in the order of 10 times. The top most curves made of filled circles correspond to current at the top (cathode 42) and bottom (anode 46). These curves generally overlap.

The TOLED 40 has a low turn on voltage (Von) of 2.7 V and small leakage current at voltages less than VON, both of which are indicators of high-quality diodes compared to conventional OLEDs. Above Von the luminance from the bottom is almost 10 times larger than the luminance from the top for almost all applied voltages.

FIG. 7b is a graph of external quantum efficiency (EQE) of the TOLED 40. The EQE of approximately 16% at 1 mA/cm2 current density from the bottom is reasonably high considering that the diode structure is not optimized to reveal the maximum emission from the bottom, but rather to maximize the bottom/top emission ratio as described. Furthermore, current efficiency of approximately 40 cd/A from the bottom (anode 46) makes the diodes appropriate for various types of display applications, e.g., display panel in a mobile device.

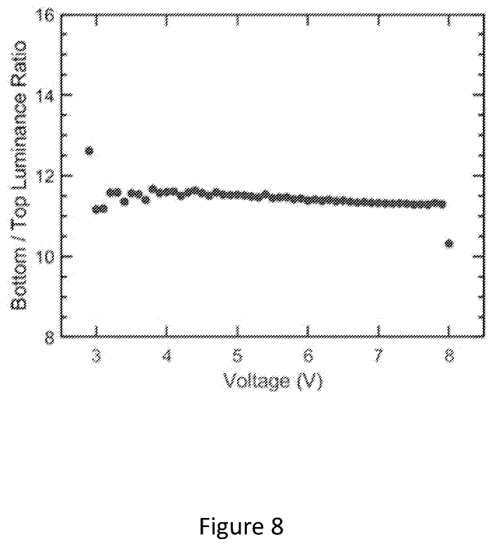

FIG. 8 is a graph of the luminance ratio of the bottom (anode 46) to top (cathode 42) sides at voltage greater than Von. The ratio is shown to exceed the expected factor of 10. For example, at a voltage of 4 V, the ratio is approximately 11.75.

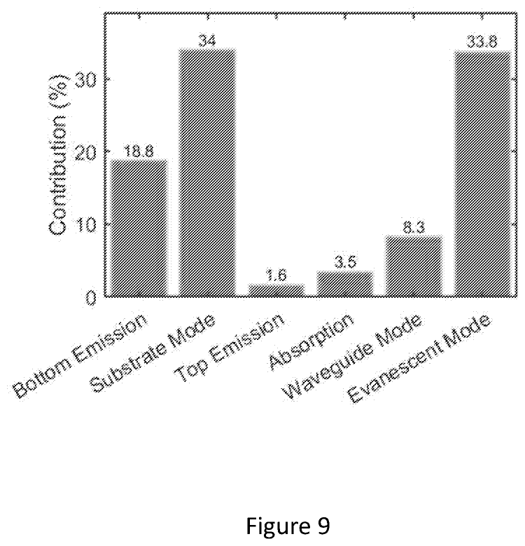

FIG. 9 is a graph of the distribution of optical modes of the TOLED 40. As illustrated, bottom emission (from the anode 46) is approximately 18.8% while top emission (from the cathode 42) is approximately 1.6% indicating a bottom/top emission ratio of greater than 10 (approximately 11.75). A percentage of substrate, waveguide mode and evanescent mode emission are also illustrated in FIG. 9.

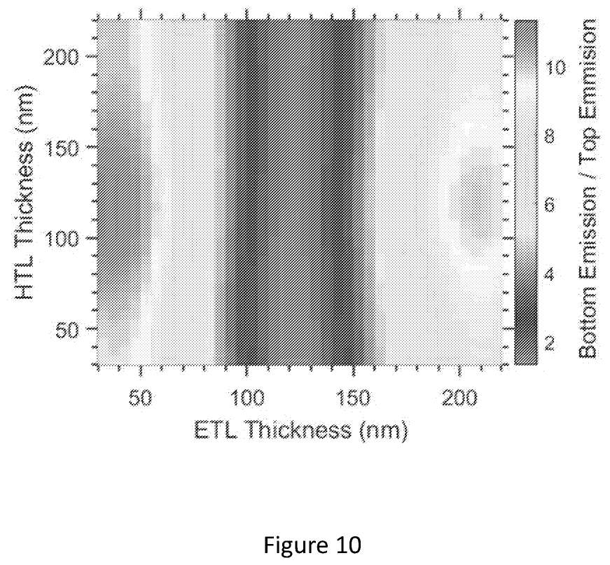

While particular thicknesses have been presented for the various layers of the organic stack 44 of the TOLED 40, one of skill in the art will appreciate other thicknesses may provide the desired privacy function. For example, the thicknesses of the HTL 52 and ETL 58 may be varied while still maximising the bottom/top emission ratio. Simulations of the TOLED 40 were performed while varying the thicknesses of the HTL 52 and ETL 58. Turning now to FIG. 10, a contour plot the ratio of bottom/top emission as a function of HTL and ETL thicknesses is illustrated. As shown, the emission ratio approximately meets or exceeds 10 when the HTL thickness falls between 70 and 170 nm and the ETL thickness falls between 30 and 50 nm.

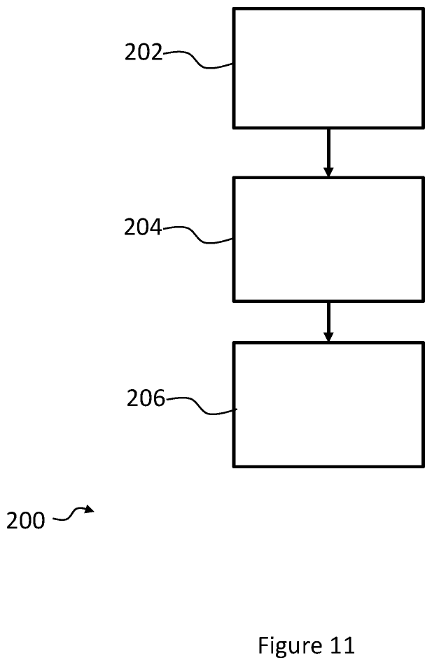

The described TOLED 40 may be manufactured according to a method illustrated in FIG. 11. The method 200 of manufacturing a transparent structure, e.g., TOLED 40, comprise tuning 202 an EML positioned between electrodes such that luminance through a first one of the electrodes is greater than luminance through the other of the electrodes. Tuning 202 may comprise selecting materials and thicknesses of layers of the organic stack of the structure, e.g., EIL, ETL, HBL, EML, HTL and HIL, to maximize the ratio of bottom/top emission, i.e., the ratio of emission through the first electrode to the emission through the second electrode.

The method 200 further comprises depositing 204 an EML on a first electrode. This may include depositing additional layers of the organic stack, e.g., EIL, ETL, HBL, HTL and HIL on the first electrode and/or EML. Depositing 204 may be preceded by depositing the first electrode (anode) on a substrate. The substrate may be pre-pattered glass. Depositing 204 may comprise thermally evaporating the EML on the first electrode.

The method 200 further comprises depositing 206 a second electrode on the EML. Depositing 206 may comprise depositing one or more layers on the EML, e.g., HBL, ETL and EIL, prior to depositing the second electrode. Depositing 206 may comprise thermally evaporating the second electrode on the EML.

The depositing steps 204, 206 may comprise thermally evaporating the described layers at ultra-high vacuum (10⁻⁸ Torr).

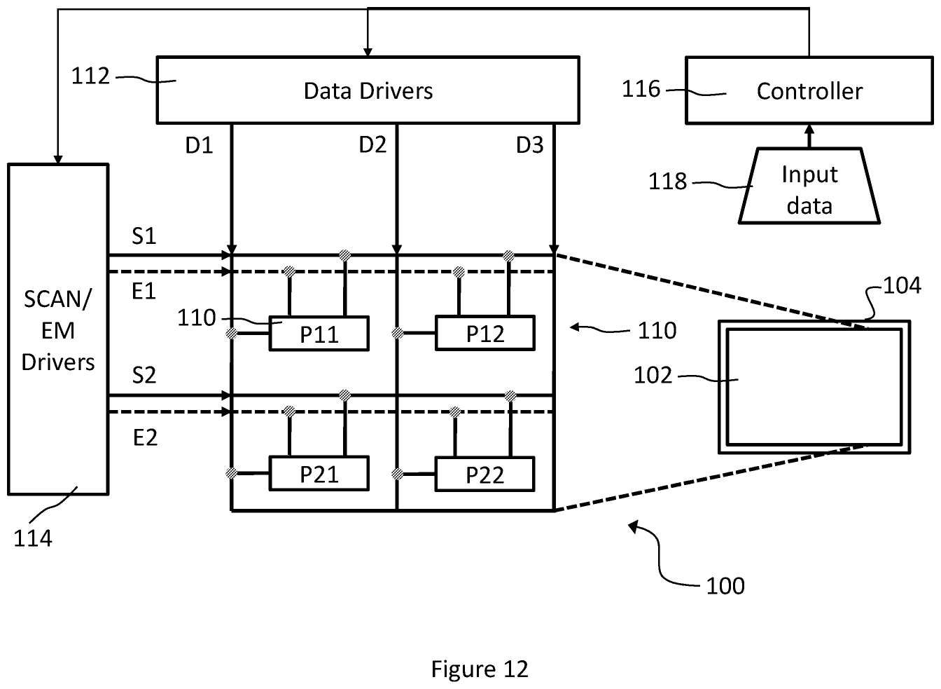

The described TOLED 40 may have a variety of use cases. For example, the TOLED 40 may be incorporated into a display system incorporating the TOLD 40. FIG. 12 is a diagram of such a display panel 102 which includes such a display system 100. As will be described, the display panel 102 includes an array of light emitting pixels including a TOLED. The display panel 102 may be surrounded by a bezel 104. The display panel 102 may define an active area of the display system 100 where information may be displayed. The bezel 104 may define an inactive area where no information is displayed.

The display system 100 is a TOLED display system which comprises an array 110 of light emitting pixels. Each light emitting pixel includes a TOLED, e.g., TOLED 40. The array of pixels 110 is driven by drivers including scan/emission (EM) drivers 114 and data drivers 112. In general, the SCAN/EM drivers 114 selects a row of pixels in the array 110, and the data drivers 112 provide data signals, e.g., voltage data, to the pixels in the selected row to light the selected TOLEDs according to image data. Signal lines such as scan lines, emission lines, and data lines are used in controlling the pixels to display images on the display panel 102.

The array 110 includes a plurality of light emitting pixels, e.g., the pixels P11 through P22. A pixel is a small element on a display that can change colour based on the image data supplied to the pixel. Each pixel within the array 110 may be addressed separately to produce various intensities of colour. The array 110 extends in a plane and includes rows and columns. A row extends horizontally across the array. For example, the first row of the array 110 includes pixels P11 and P12. A column extends vertically down the display system 100. For example, the first column of the array 110 includes pixels P11 and P21. Only a finite number of pixels are illustrated in FIG. 12 for clarity of presentation. One of skill in the art will appreciate several million pixels may be array 110 to provide higher image resolution.

The SCAN/EM drivers 114 are integrated, i.e., stacked, row line drivers that supply signals to rows of the array 110. In particular, the SCAN/EM drivers 114 supply signals S1-S2 and emission signals E1-E2 to the rows of pixels. The data drivers 112 supply signals to columns of the array 110. In particular, the data drivers 112 supply data signals D1-D3 to the column of pixels. Each pixel is the array 110 is addressable by a horizontal scan line and emission line, and a vertical data line. For example, pixel P21 is addressable by the scan line S2, emission line E2 and data line D1.

The display system 200 further includes a controller 116 which receive input data 118 for display. The controller 116 provides input, e.g., clock signals and start pulses, to the SCAN/EM drivers 114 and input, e.g., image data, to the data drivers 112.

Based on the input received from the controller 116, the SCAN/EM drivers 114 and data drivers 112 provide signals to the pixels enabling the pixels of the array 110 to reproduce an image according to the input data 118 on the display panel 102. The SCAN/EM drivers 114 and the data drivers 112 provide the signals to the pixels via the scan lines, emission lines and data lines. In particular, the SCAN/EM drivers 114 select a scan line and control an emission operation of the pixels on that line. The data drivers 112 provides data signals to the pixels addressable by the selected scan line to light the selected TOLEDs according to the input data 118.

In this way, the TOLEDs of the display panel 102 emit light according to the input data to present information on the display panel 102. As described, the information being displayed by viewable on one face of the transparent display panel 102, while the information is not visible on the opposite face of the panel 102. In other words, the display panel 102 emits light in one direction, but does not emit substantial light in an opposite direction. Due to the TOLEDs of the pixels of the array 110 being tuned to emit greater luminance in one direction than another, the information is only visible in one direction. This provides a privacy function and prevents unauthorised users from viewing content on the display panel 102.

It should be understood that the examples provided are merely exemplary of the present disclosure, and that various modifications may be made thereto.

1. A transparent structure for emitting light, the transparent structure comprising an emissive layer (EML) positioned between first and second electrodes, the EML tuned such that luminance through the first electrode is greater than luminance through the second electrode.

2. The transparent structure of claim 1, the EML tuned such that luminance through the first electrode is at least ten times greater than luminance through the second electrode.

3. The transparent structure of claim 1, wherein the first electrode comprises indium tin oxide (ITO).

4. The transparent structure of claim 1, wherein the first electrode has a thickness of from 50 to 150 nm.

5. The transparent structure of claim 1, wherein the second electrode comprises silver and aluminium.

6. The transparent structure of claim 1, wherein the second electrode comprises an aluminium layer having a thickness of 1±1 nm and a silver layer having a thickness of 20±2 nm.

7. The transparent structure of claim 1, wherein the EML comprises 4,4′-Bis(N-carbazolyl)-1,1′-biphenyl (CBP) doped with 7% Ir(ppy)₂acac.

8. The transparent structure of claim 1, wherein the EML has a thickness of 20±5 nm.

9. The transparent structure of claim 1, further comprising an electron injection layer (EIL), an electron transport layer (ETL), a hole blocking layer (HBL), a hole transport layer (HTL), and a hole injection layer (HIL), and combinations thereof.

10. The transparent structure of claim 9, wherein the EIL has a thickness of 2±2 nm.

11. The transparent structure of claim 9, wherein the ETL has a thickness of 40±10 nm.

12. The transparent structure of claim 9, wherein the HBL has a thickness of 10±2 nm.

13. The transparent structure of claim 9, wherein the HTL has a thickness of 130±30 nm.

14. The transparent structure of claim 9, wherein the HIL has a thickness of 5±2 nm.

15. The transparent structure of claim 9, wherein the HTL has a thickness of 70-170 nm and the ETL has a thickness of 30-50 nm.

16. A method of manufacturing a transparent organic light-emitting diode (TOLED), the method comprising tuning an emissive layer (EML) positioned between first and second electrodes such that luminance through the first electrode is greater than luminance through the second electrode.

17. The method of claim 16, further comprising:
depositing an emissive layer (EML) on a first electrode.

18. The method of claim 16, further comprising:
depositing a second electrode on the EML.

19. A transparent organic light-emitting diode (TOLED) comprising an emissive layer (EML) positioned between first and second electrodes, the EML tuned such that luminance through the first electrode is greater than luminance through the second electrode.

20. A display panel comprising an array of light emitting pixels, each light emitting pixel comprising the TOLED of claim 17.
